(19) United States
(12) Patent Application Publication
(10) Pub. No.: US 2024/0363596 A1
(43) Pub. Date: Oct. 31, 2024

(54) DISPLAY DEVICE

(71) Applicant: Samsung Display Co., LTD., Yongin-si (KR)

(72) Inventors: Joo Woan CHO, Yongin-si (KR); Jin Taek PARK, Yongin-si (KR); Byeong Hwa CHOI, Yongin-si (KR); Jae Ho CHOI, Yongin-si (KR); Hae Yun CHOI, Yongin-si (KR)

(21) Appl. No.: 18/415,183

(22) Filed: Jan. 17, 2024

(30) Foreign Application Priority Data
Apr. 27, 2023 (KR) 10-2023-0055361

(51) Int. Cl. H01L 25/075; H01L 33/60; H01L 33/62; H05K 1/18

(52) U.S. Cl. CPC H01L 25/0753; H01L 33/60; H01L 33/62; H05K 1/189; H05K 2201/10128

(57) ABSTRACT

The present disclosure may provide a display device. According to one or more embodiments, the display device includes a first display panel for emitting a first light, a second display panel for emitting second light, a third display panel for emitting third light, and a light coupler for combining the first light, the second light, and the third light, and for outputting combined light, and a circuit board on a first surface of the light coupler, and electrically connected to the first display panel, to the second display panel, and to the third display panel, wherein the first display panel, the second display panel, and the third display panel are respectively on a second surface, a third surface, and a fourth surface of the light coupler.

### CROSS-REFERENCE TO RELATED APPLICATION

The present application claims priority to, and the benefit of, Korean Patent Application No. 10-2023-0055361, filed on Apr. 27, 2023, in the Korean Intellectual Property Office, the entire disclosure of which is incorporated herein by reference.

### BACKGROUND

### 1. Field

The present disclosure relates to a display device.

### 2. Description of the Related Art

As the information society develops, the demand for a display device for displaying an image is increasing in various forms. The display device may be a flat panel display, such as a liquid crystal display, a field emission display, or a light-emitting display panel. The light-emitting display device may include an organic light-emitting diode device including an organic light-emitting diode element as a light-emitting element, an inorganic light-emitting element including an inorganic semiconductor element as a light-emitting element, or a subminiature light-emitting diode element (or a micro light-emitting diode element) as a light-emitting element.

Recently, a head mounted display including a light-emitting display device has been developed. The head mounted display (HMD) is a spectacle-type monitor device of virtual reality (VR) or augmented reality (AR) that the user wears in the form of glasses or a helmet, and the focus is formed at a close distance in front of the user's eyes.

A high-resolution micro light-emitting diode display panel including the micro light-emitting diode element may be applied to the head mounted display. The micro light-emitting diode display panels may be used for implementing monochrome or full-color displays.

### SUMMARY

Aspects of embodiments of the present disclosure provide a display device capable of implementing the full-color display by using a plurality of light-emitting diode display panels connected to one circuit board, sharing a connector, and implementing different monochrome displays.

Another aspects of embodiments of the present disclosure provide a display device capable of implementing a full-color display by using a plurality of light-emitting diode display panels that share a connector included in one circuit board, and implement different monochromatic displays.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments, a display device includes a first display panel for emitting a first light, a second display panel for emitting second light, a third display panel for emitting third light, and a light coupler for combining the first light, the second light, and the third light, and for outputting combined light, and a circuit board on a first surface of the light coupler, and electrically connected to the first display panel, to the second display panel, and to the third display panel, wherein the first display panel, the second display panel, and the third display panel are respectively on a second surface, a third surface, and a fourth surface of the light coupler.

The circuit board may include a connector or a connector connection unit connected to an external device, wherein the connector or the connector connection unit is electrically connected to the first display panel, to the second display panel, and to the third display panel.

The circuit board may include a first circuit pad unit electrically connected to the first display panel, a second circuit pad unit electrically connected to the second display panel, a third circuit pad unit electrically connected to the third display panel, a first conductive line connected from the connector or the connector connection unit to the first circuit pad unit, a second conductive line connected from the connector or the connector connection unit to the second circuit pad unit, and a third conductive line connected from the connector or the connector connection unit to the third circuit pad unit.

The display device may further include a bent first flexible circuit board between the first display panel and the circuit board, a bent second flexible circuit board between the second display panel and the circuit board, and a bent third flexible circuit board between the third display panel and the circuit board.

The first flexible circuit board may electrically connect the first circuit pad unit and the first display panel, wherein the second flexible circuit board electrically connects the second circuit pad unit and the second display panel, and wherein the third flexible circuit board electrically connects the third circuit pad unit and the third display panel.

The first surface may be perpendicular to the second surface, to the third surface, and to the fourth surface, wherein the second surface and the third surface face each other.

The light coupler may reflect the first light, and may include a first reflective transmissive film that transmits the second light and the third light, and a second reflective transmissive film that reflects the third light and transmits the first light and the second light.

The display device may further include one or more lenses in an output direction of the combined light from the light coupler to converge or focus the combined light in one direction.

The circuit board may further include passive elements for applying separate signals to the first display panel, to the second display panel, and to the third display panel.

The first display panel, the second display panel, the third display panel, and the light coupler may be fixed by an adhesive.

The adhesive may be one of cement or optical adhesive.

The adhesive may include at least one of a black-based dye or a metal.

The display device may further include a housing surrounding the display panel, and coupling the display panel and the light coupler.

According to one or more embodiments, a display device includes a first display panel for emitting a first light, a second display panel for emitting second light, a third display panel for emitting third light, and a circuit board including first conductive lines connected to the first display panel, second conductive lines connected to the second display panel, third conductive lines connected to the third display panel, and a connector connected to an external device and connected to the first conductive lines, the second conductive lines, and the third conductive lines.

The circuit board may further include passive elements for applying separate signals to the first display panel, to the second display panel, and to the third display panel.

The circuit board may include a first circuit pad unit electrically connected to the first display panel, a second circuit pad unit electrically connected to the second display panel, a third circuit pad unit electrically connected to the third display panel, one of the first conductive lines connected from the connector or a connector connection unit to the first circuit pad unit, one of the a second conductive lines connected from the connector or the connector connection unit to the second circuit pad unit, and one of the a third conductive lines connected from the connector or the connector connection unit to the third circuit pad unit.

The display device may further include a first flexible circuit board between the first display panel and the circuit board, a second flexible circuit board between the second display panel and the circuit board, and a third flexible circuit board between the third display panel and the circuit board, wherein the first flexible circuit board, the second flexible circuit board, and the third flexible circuit board are bent.

According to one or more embodiments, a display device includes a first display panel for emitting a first light, a second display panel for emitting second light, a third display panel for emitting third light, a circuit board including a connector connected to an external device, and a passive element for applying separate signals to the first display panel, to the second display panel, and to the third display panel, and flexible circuit boards connecting each of the first display panel, the second display panel, and the third display panel to the circuit board, wherein the connector is electrically connected to the first display panel, to the second display panel, and to the third display panel.

The display device may further include a light coupler for combining the first light, the second light, and the third light, and for outputting combined light, and one or more lenses in an output direction of the combined light from the light coupler to converge or focus the combined light in one direction.

The light coupler may be configured to reflect the first light, and may include a first reflective transmissive film for transmitting the second light and the third light, and a second reflective transmissive film for reflecting the third light and for transmitting the first light and the second light.

According to the display device according to embodiments, a full-color display may be implemented using one circuit board and a plurality of light-emitting diode display panels implementing different monochromatic displays.

In addition, it is possible to provide a display device capable of miniaturizing and lightening the display device, and having a low cost by sharing a single connector with different monochrome displays.

However, the aspects of the present disclosure are not limited to the aforementioned effects, and various other effects are included in the present specification.

### BRIEF DESCRIPTION OF THE DRAWINGS

FIG. 1 is a side perspective view of a display device according to one or more embodiments.

FIG. 2 is a side perspective view of the display device of FIG. 1 viewed from another angle.

FIG. 3 is a plan view of the display device of FIG. 1.

FIG. 4 is a side view of the display device of FIG. 1.

FIG. 5 is a bottom view of the display device of FIG. 1.

FIG. 6 is a graph illustrating main peak wavelengths of first to third lights and ranges of first and second transmissive films.

FIG. 7 is a front plan view of a display device in which each display panel is located on one plane according to one or more embodiments.

FIG. 8 is a plan view of a bottom surface of the display device of FIG. 7.

FIG. 9 is an enlarged view of area B of FIG. 7.

FIG. 10 is an enlarged view of area A of FIG. 8.

FIG. 11 is a plan view of a bottom surface of a display device in which each display panel is located on one plane according to one or more other embodiments.

FIG. 12 is an enlarged view of area C of FIG. 11.

FIG. 13 is a cross-sectional view illustrating a display panel taken along line III-III′ of FIG. 7.

FIG. 14 is a cross-sectional view illustrating a display panel taken along line IV-IV′ of FIG. 7.

FIG. 15 is a cross-sectional view illustrating a display panel taken along line V-V′ of FIG. 7.

FIG. 16 is an enlarged cross-sectional view of a light-emitting element according to one or more embodiments.

FIG. 17 is a pixel circuit diagram of a display device according to one or more embodiments.

FIG. 18 is a perspective view of a display device using a first coupler according to one or more embodiments.

FIG. 19 is a perspective view of a display device using a second coupler according to one or more other embodiments.

FIG. 20 is a perspective view of a display device using a housing according to one or more other embodiments.

FIG. 21 is a diagram schematically showing a virtual reality device including a display device according to one or more embodiments.

FIG. 22 is a diagram schematically showing a smart device including a display device according to one or more embodiments.

FIG. 23 is a diagram schematically showing a vehicle including a display device according to one or more embodiments.

FIG. 24. is a diagram schematically showing a transparent display device including a display device according to one or more embodiments.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

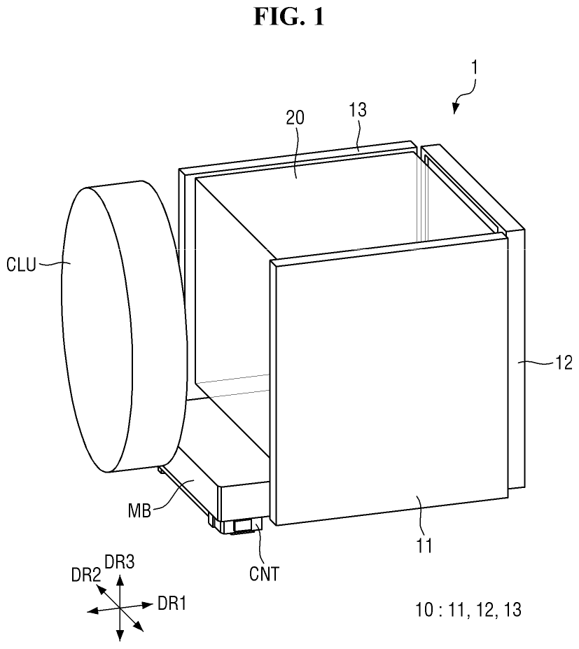

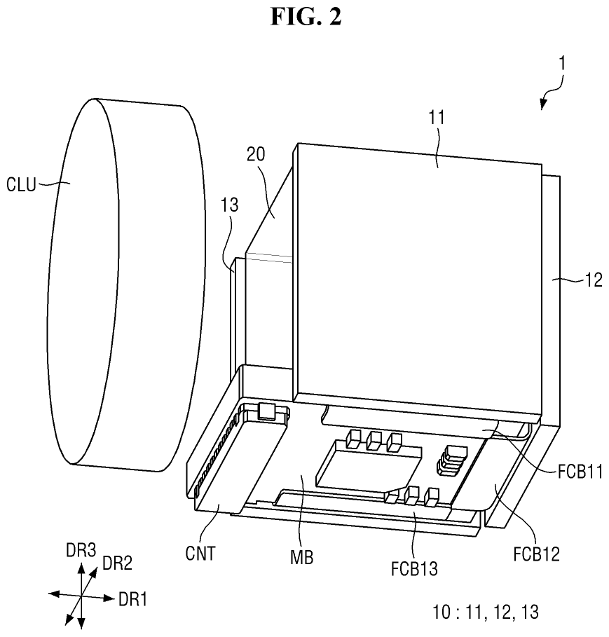

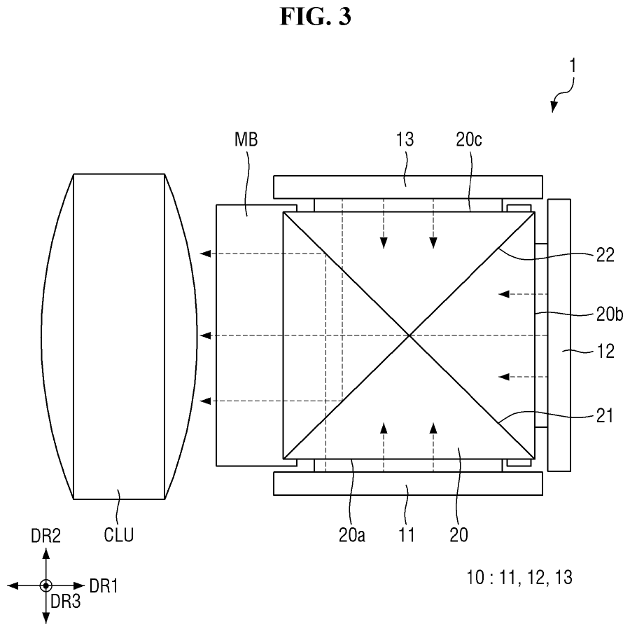

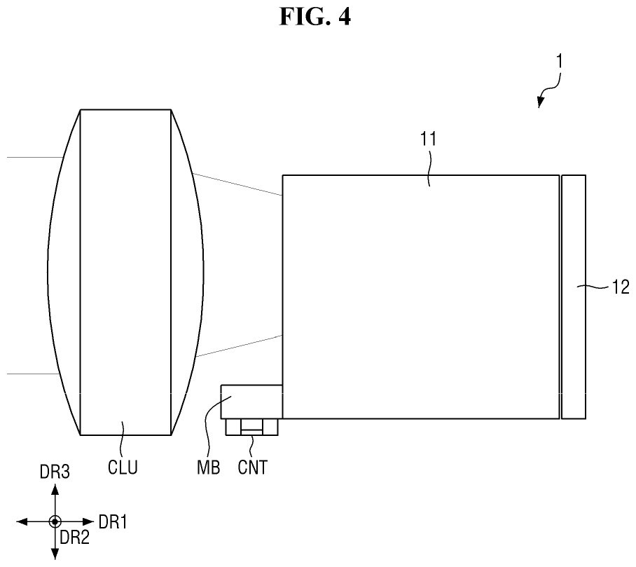

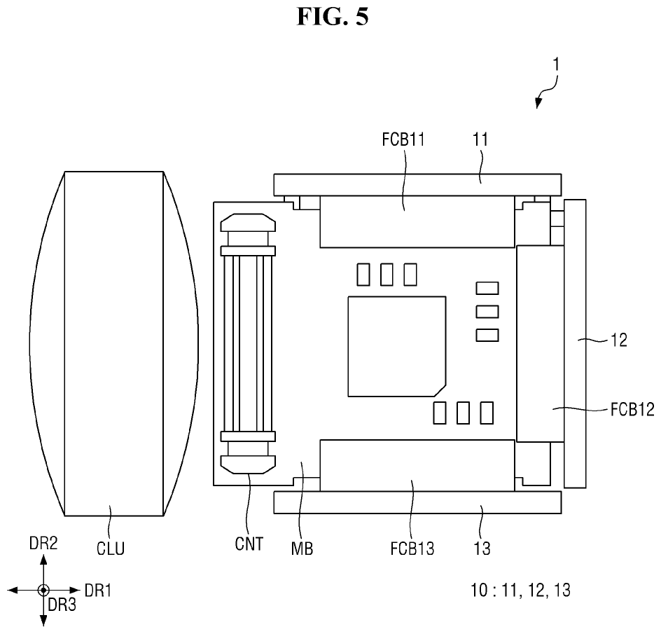

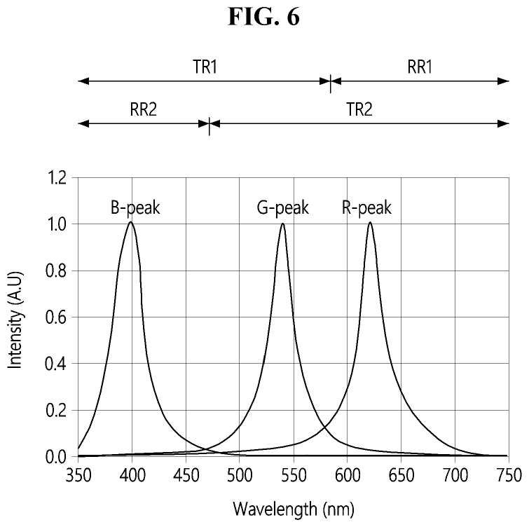

FIG. 1 is a side perspective view of a display device according to one or more embodiments. FIG. 2 is a side perspective view of the display device of FIG. 1 viewed from another angle. FIG. 3 is a plan view of the display device of FIG. 1. FIG. 4 is a side view of the display device of FIG. 1. FIG. 5 is a bottom view of the display device of FIG. 1. FIG. 6 is a graph illustrating main peak wavelengths of first to third lights and ranges of first and second transmissive films.

Although the display device according to one or more embodiments has been mainly described as a subminiature light-emitting diode display (micro or nano light-emitting diode display) including a subminiature light-emitting diode (micro or nano light-emitting diode) as the light-emitting element LE, the embodiments of the present specification are not limited thereto.

In addition, in FIG. 1, although the display device according to one or more embodiments has been mainly described as a light-emitting diode on silicon (LEDoS) in which light-emitting diodes are located on a semiconductor circuit layer formed by a semiconductor process using a silicon wafer, the embodiments of the present specification are not limited thereto.

In addition, in FIGS. 1 to 2, a first direction DR1 indicates a horizontal direction of a circuit board MB, a second direction DR2 indicates a vertical direction of the circuit board MB, and a third direction DR3 indicates a thickness direction of the circuit board MB. In this case, “left”, “right”, “top”, and “bottom” indicate directions when the circuit board MB is viewed from a plane. For example, “right” refers to one side of the first direction DR1, “left” refers to the other side of the first direction DR1, “upper side” refers to one side of the second direction DR2, and “lower side” refers to the other side in the second direction DR2. Also, “upper” may refer to one side in the third direction DR3 and “lower” may refer to the other side in the third direction DR3.

Referring to FIGS. 1 to 6, a display device 1 according to one or more embodiments may include a display panel 10, a circuit board MB, and a light coupler (e.g., a light-coupling member, or light-combining member) 20. Also, the display device 1 may further include a lens (e.g., a projection optical member) CLU and a plurality of flexible circuit boards FCB.

The display panel 10 may have a rectangular planar shape. However, the planar shape of the display panel 10 is not limited thereto, and may have a polygonal, circular, elliptical, or atypical planar shape other than a rectangle.

The display panels 10 may include a first display panel 11 for emitting a first light, a second display panel 12 for emitting a second light, and a third display panel 13 for emitting a third light. Each of the display panels 11, 12, and 13 may emit monochromatic light.

The first display panel 11 may emit first light. The first light of the first display panel 11 may be light in a red wavelength band. The red wavelength band may be about 600 nm to about 750 nm, but embodiments of the present specification are not limited thereto.

The second display panel 12 may emit second light. The second light of the second display panel 12 may be light in a green wavelength band. The green wavelength band may be about 480 nm to about 560 nm, but embodiments of the present specification are not limited thereto.

The third display panel 13 may emit third light. The third light of the third display panel 13 may be light in a blue wavelength band. The blue wavelength band may be about 370 nm to about 460 nm, but embodiments of the present specification are not limited thereto.

The light coupler 20 receives light emitted from different directions, and effectively couples the light so that the light generally propagates in the same direction. For example, the light coupler 20 may be a prism having a reflective inner surface for redirecting light received from the display panel 10.

In one or more embodiments, the light coupler 20 is a regular hexahedron, and may be surrounded by the first display panel 11, the second display panel 12, and the third display panel 13. For example, the first display panel 11, the second display panel 12, and the third display panel 13 may be located on the second, third and fourth surfaces of the light coupler 20, respectively.

The light coupler 20 may be a prism having a shape, such as a rectangular parallelepiped or a regular hexahedron formed by combining four triangular prisms. The light coupler 20 may include a first side surface 20a facing the first display panel 11, a second side surface 20b facing the second display panel 12, and a third side surface 20c facing the third display panel 13 in plan view.

The first side surface 20a of the light coupler 20 and the third side surface 20c of the light coupler 20 are extended in the third direction DR3 on the plane and may face each other. The first side surface 20a of the light coupler 20 and the third side surface 20c of the light coupler 20 may be extended in a direction (e.g., DR1) that is perpendicular to a direction (e.g., DR2) in which the second side surface 20b of the light coupler 20 extends.

The light coupler 20 may be an optical means for concentrating the first to third lights of the first to third display panels 11, 12, and 13 to one place, and combining them into one. The first light of the first display panel 11 may be perpendicularly incident to the first side surface 20a of the light coupler 20, the second light of the second display panel 12 may be perpendicularly incident to the second side surface 20b of the light coupler 20, and third light from the third display panel 13 may be perpendicularly incident to the third side surface 20c of the light coupler 20.

The light coupler 20 may include a first reflective transmissive film 21 and a second reflective transmissive film 22, as shown in FIG. 3.

As shown in FIG. 6, the first reflective transmissive film 21 may have a first light reflection range RR1 and a first light transmission range TR1. The first reflective transmissive film 21 reflects first light having a wavelength value within the first light reflection range RR1, and may transmit other light having a wavelength value within the first light transmission range TR1, that is, the second light and the third light.

As shown in FIG. 6, the second reflective transmissive film 22 may have a second light reflection range RR2 and a second light transmission range TR2. The second reflective transmissive film 22 reflects third light having a wavelength value within the second light reflection range RR2, and may transmit other light having a wavelength value within the second light transmission range TR2, that is, the first light and the second light.

The first light incident on the first side surface 20a of the light coupler 20 may penetrate the second reflective transmissive film 22 and may be reflected by the first reflective transmissive film 21. The third light incident on the third side surface 20c of the light coupler 20 may penetrate the first reflective transmissive film 21 and may be reflected by the second reflective transmissive film 22. Because the first reflective transmissive film 21 and the second reflective transmissive film 22 of the light coupler 20 do not reflect the second light, the second light incident on the second side surface 20b of the light coupler 20 may penetrate and proceed as it is. In this way, the first to third lights may be focused by the light coupler 20 and emitted as white light.

The circuit board MB may be located on the first surface of the light coupler 20 on which the first display panel 11, the second display panel 12, and the third display panel 13 is not located. The first face may be perpendicular to the second face, the third face, and the fourth face. Accordingly, the first display panel 11, the second display panel 12, and the third display panel 13 may be located in a direction perpendicular to the circuit board MB.

The circuit board MB is electrically connected to the first display panel 11, the second display panel 12, and the third display panel 13. That is, the first display panel 11, the second display panel 12, and the third display panel 13 are connected to one circuit board MB.

The circuit board MB may include various active elements or passive elements for driving the display panel 10. For example, the circuit board MB may include a timing controller, a display driving IC, and the like. The timing controller may be mounted on the circuit board MB as a separate member, or may be configured as an integrated circuit. The plurality of first display panels 11, second display panels 12, and third display panels 13 connected to one circuit board MB may share various active elements or passive elements included in the connected circuit board MB. For example, the timing controller or driving IC may apply signals to each of the first display panel 11, the second display panel 12, and the third display panel 13.

In addition, the circuit board MB may include a connector CNT for connection to an external device, for example, a power supply device. The connector CNT may be electrically connected to the first display panel 11, the second display panel 12, and the third display panel 13. For example, the connector CNT is connected to an external power supply, and may transmit supplied power to the first display panel 11, the second display panel 12, and the third display panel 13 electrically connected thereto.

According to one or more embodiments, the power may be transmitted to the first display panel 11, the second display panel 12, and the third display panel 13 through one connector CNT. Also, according to one or more embodiments, the first display panel 11, the second display panel 12, and the third display panel 13 may be suitably controlled through one circuit board MB.

The plurality of flexible circuit boards FCB may be flexible circuit boards. The flexible circuit board FCB, for example, may be a flexible film, such as a flexible printed circuit board (FPCB), a printed circuit board (PCB), a flexible printed circuit (FPC) or a chip on film (COF).

The flexible circuit board FCB may include a first flexible circuit board FCB11, a second flexible circuit board FCB12, and a third flexible circuit board FCB13.

The first flexible circuit board FCB11 may be located between the first display panel 11 and the circuit board MB to connect the first display panel 11 and the circuit board MB. When the first flexible circuit board FCB11 is bent, the first display panel 11 and the circuit board MB may face different directions. For example, because the first flexible circuit board FCB11 may be bent at a substantially right angle, the first display panel 11 and the circuit board MB may be located substantially perpendicular to each other.

The second flexible circuit board FCB12 may be located between the second display panel 12 and the circuit board MB to connect the second display panel 12 and the circuit board MB. When the second flexible circuit board FCB12 is bent, the second display panel 12 and the circuit board MB may face different directions. For example, because the second flexible circuit board FCB12 may be bent at the substantially right angle, the second display panel 12 and the circuit board MB may be located substantially perpendicular to each other.

The third flexible circuit board FCB13 is located between the third display panel 13 and the main circuit board MCB to connect the third display panel 13 and the circuit board MB. When the third flexible circuit board FCB13 is bent, the third display panel 13 and the circuit board MB may face different directions. Because the third flexible circuit board FCB13 may be bent at the substantially right angle, the third display panel 13 and the circuit board MB may be located substantially perpendicular to each other.

The lens CLU is located in an output direction of light coupled from the light coupler 20.

The lens CLU may be a lens assembly including one or more lenses that converge or focus the light coupled from the light coupler 20 in one direction.

In the display device 1 according to one or more embodiments, a display of multi-color light may be implemented by focusing mono-color lights emitted from the first to third display panels 11, 12, and 13 at the light coupler 20.

In addition, because the first to third display panels 11, 12, and 13 are located on one circuit board MB and connected to one connector CNT, the display device of the display device 1 may be miniaturized and portable, and the cost of the circuit board MB may be reduced.

Hereinafter, the display device 1 in an unfolded state without bending the flexible circuit board FCB except for the light coupler 20 will be described.

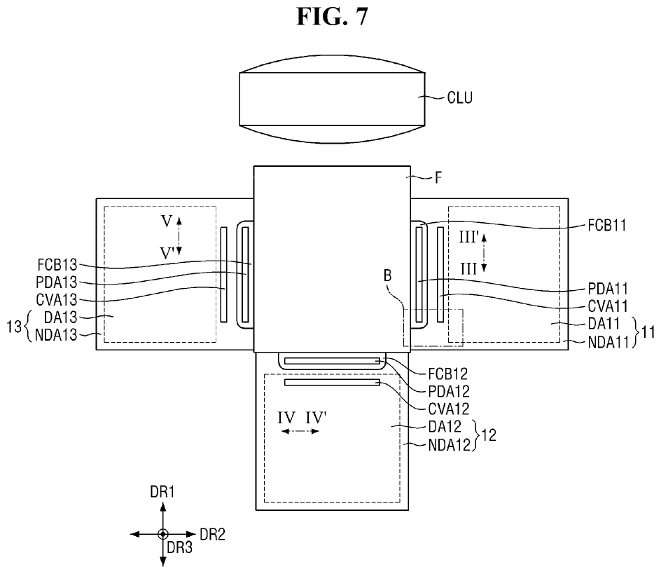

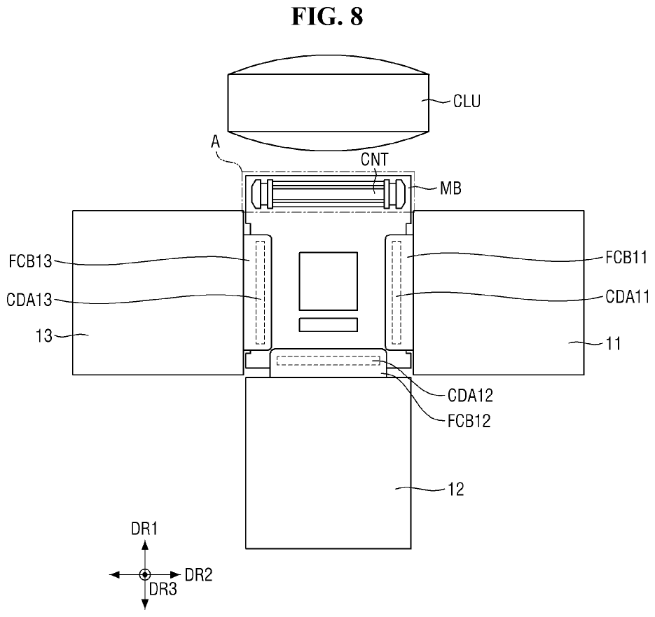

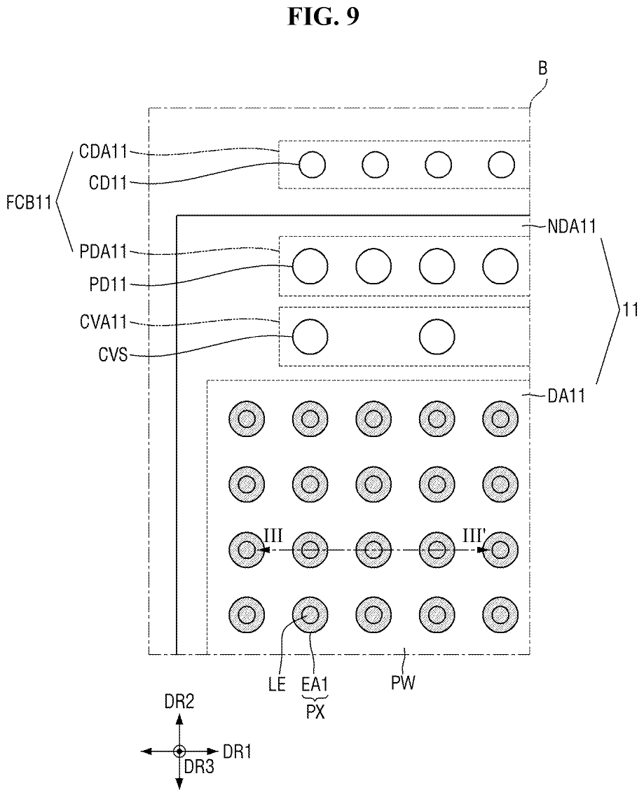

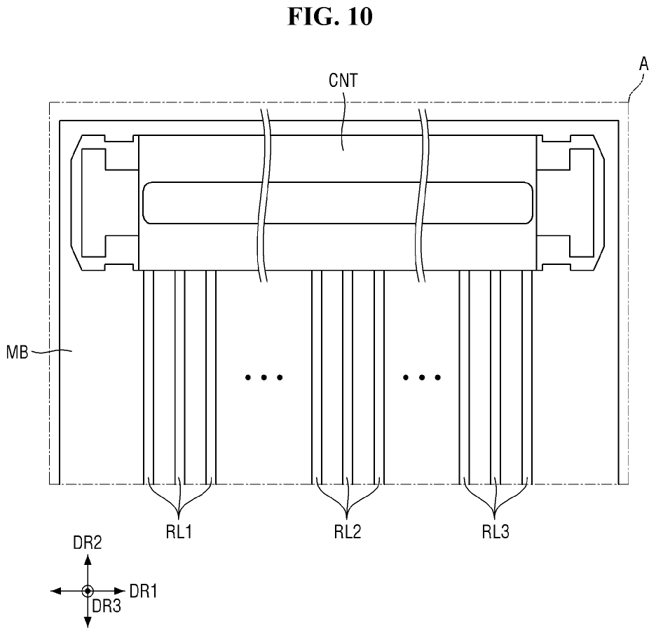

FIG. 7 is a front plan view of a display device in which each display panel is located on one plane according to one or more embodiments. FIG. 8 is a plan view of a bottom surface of the display device of FIG. 7. FIG. 9 is an enlarged view of area B of FIG. 7. FIG. 10 is an enlarged view of area A of FIG. 8.

Referring to FIGS. 7 and 9, the first display panel 11, the second display panel 12, the third display panel 13, and the light coupler 20 may be located clockwise around the circuit board MB of the display device 1.

Each of the display panels 11, 12, and 13 may include a display area DA and a non-display area NDA.

The display area DA may be an area where an image is displayed, and the non-display area NDA may be an area where no image is displayed. Although the planar shape of the display area DA is a rectangle, it is not limited thereto. The non-display area NDA may be located around the display area DA. The non-display area NDA may be located to surround the display area DA.

For example, the first display panel 11 may include a first display area DA11 and a first non-display area NDA11, the second display panel 12 may include a second display area DA12 and a second non-display area NDA12, and the third display panel 13 may include a third display area DA13 and a third non-display area NDA13.

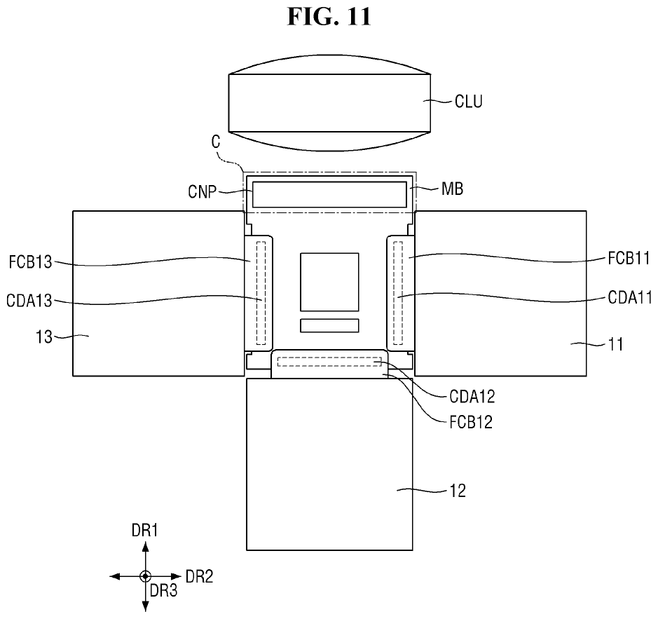

The first non-display area NDA11 of the first display panel 11 may include a first common voltage supply area CVA11 and a first pad unit PDA11. The first common voltage supply area CVA11 may be located between the first pad unit PDA11 and the first display area DA1. The first common voltage supply area CVA11 may include a plurality of common voltage supply units CVS connected to a common electrode CE. The common voltage may be supplied to the common electrode (CE of FIG. 11) through the plurality of common voltage supply units CVS.

The plurality of common voltage supply units CVS of the first common voltage supply area CVA11 may be electrically connected to one of the first pads PD11 of the first pad unit PDA11. That is, the plurality of common voltage supply units CVS of the first common voltage supply area CVA11 may receive a common voltage from one of the first pads PD11 of the first pad unit PDA11.

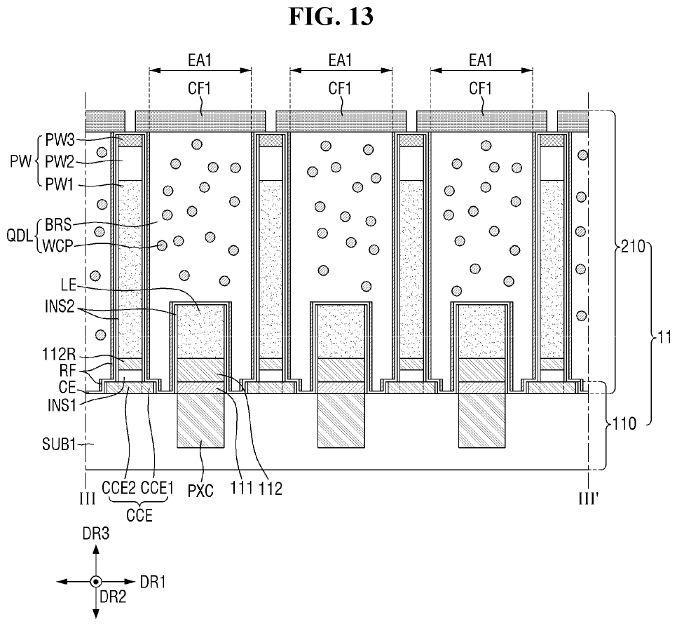

Each of the first pad PD11 and the common voltage supply unit CVS may be an exposed electrode exposed from a first substrate SUB1, which will be described later with reference to FIG. 13. Each of the first pad PD11 and common voltage supply unit CVS may include the same material as the pixel electrodes (111 of FIG. 13). For example, each of the first pad PD11 and the common voltage supply unit CVS may include aluminum (Al).

The first pad unit PDA11 may be located above the first display panel 11. The first pad unit PDA11 may include first pads PD11 connected to the first flexible circuit board FCB11 of the circuit board MB.

The circuit board MB located adjacent to the first display panel 11 may include a first circuit pad unit CDA11.

The first circuit pad unit CDA11 may be located adjacent to the first pad unit PDA11 of the first display panel 11. The first circuit pad unit CDA11 may include first circuit pads CD11 connected to the first display panel 11. Each of the first pad units PD11 of the first display panel 11 may be electrically connected to the first circuit pad CD11. For example, each of the first pad units PD11 of the first display panel 11 may be connected to the first circuit pad CD11 by the flexible circuit board FCB. In another modification, each of the first pad units PD11 of the first display panel 11 may be electrically connected to the first circuit pad CD11 through a conductive connector, such as a wire WR.

Referring to FIG. 7, each of the plurality of pixels PX included in the second display panel 12 and the third display panel 13 is different from the first display panel 11 including a first emitting area EA1, in that they respectively include a second light-emitting area EA2 and a third light-emitting area EA3. An enlarged view of the second display panel 12 and an enlarged view of the third display panel 13 are omitted in a portion corresponding to FIG. 8 illustrating an enlarged view B.

Referring to FIG. 10, the connector mounted on the circuit board MB will be described in detail.

The circuit board MB may include the connector CNT connected to an external device. The connector CNT may be a coupler or coupling member for electrically connecting the plurality of first to third conductive lines RL1, RL2, and RL3 included in the circuit board MB with other external devices.

In one or more embodiments, a plurality of first conductive lines RL1 connected to the connector CNT may be connected to the first display panel 11. For example, the first conductive lines RL1 is connected to the first circuit pad CD11 of the circuit board MB described with reference to FIG. 9. The first circuit pad CD11 is connected to the first pad unit PD11 of the first display panel 11 through the flexible circuit board FCB. Accordingly, the first conductive line RL1 may be connected to the first display panel 11.

Similarly, a plurality of second conductive lines RL2 connected to the connector CNT may be connected to the second display panel 12. The plurality of third conductive lines RL3 connected to the connector CNT may be connected to the third display panel 13.

The connector CNT may be connected to the first display panel 11, the second display panel 12, and the third display panel 13 through the connected first to third conductive lines RL1, RL2, and RL3.

The display device 1 according to one or more embodiments may apply separate signals to the first to third display panels 11, 12, and 13 connected to one circuit board MB. Accordingly, the display device 1 may be driven according to a desired image.

Accordingly, miniaturization and portability of the display device may be possible. Also, cost reduction may be achieved by using one circuit board.

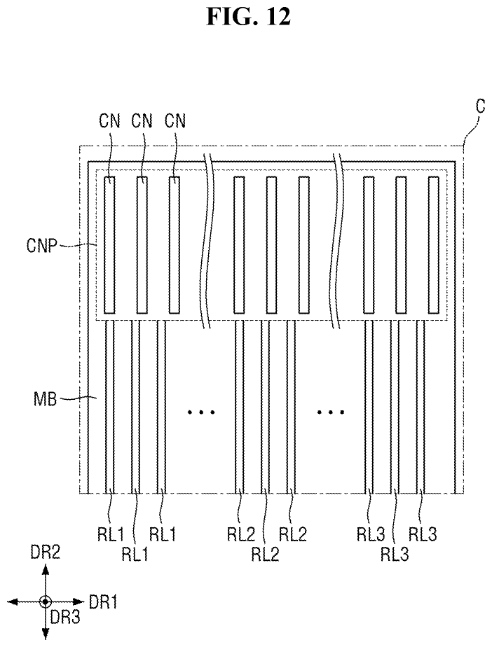

FIG. 11 is a plan view of a bottom surface of a display device in which each display panel is located on one plane according to one or more other embodiments. FIG. 12 is an enlarged view of area C of FIG. 11.

Referring to FIGS. 11 and 12, the circuit board MB may include a connector connection unit CNP connected to an external connector. The connector connection unit CNP may be a coupler for electrically connecting the plurality of first to third conductive lines RL1, RL2, and RL3 included in the circuit board MB to the first to third display panels 11, 12, and 13. In one or more embodiments, the first conductive line RL1 may be connected to the first display panel 11. The second conductive line RL2 may be connected to the second display panel 12. The third conductive line RL3 may be connected to the third display panel 13.

The connector connection unit CNP may include a plurality of metal patterns CN. The plurality of metal patterns CN may be connected to an external connector to apply electrical signals to the connected first display panel 11, the second display panel 12, and the third display panel 13 through the first to third conductive lines RL1, RL2, and RL3.

In addition, the display device 1 according to one or more embodiments does not use individual circuit boards for each of the display panels 11, 12, and 13 and may apply a signal using a connector connection unit located on one circuit board MB. Accordingly, miniaturization and portability of the display device may be possible. Also, cost reduction may be achieved by using one circuit board.

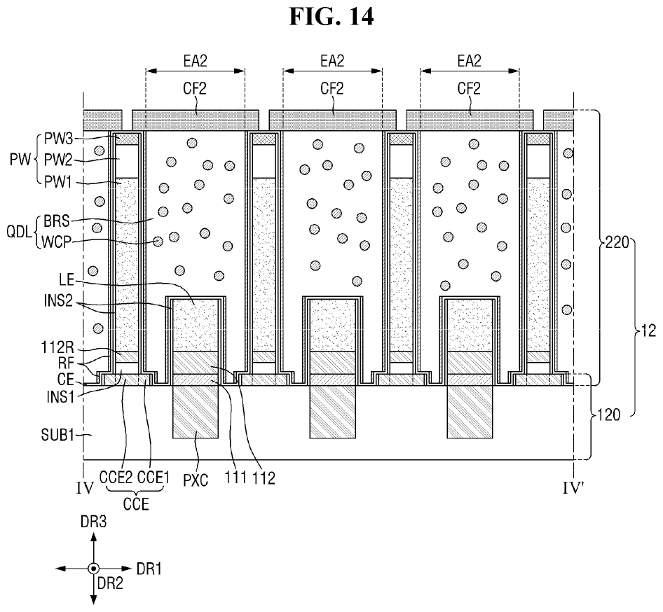

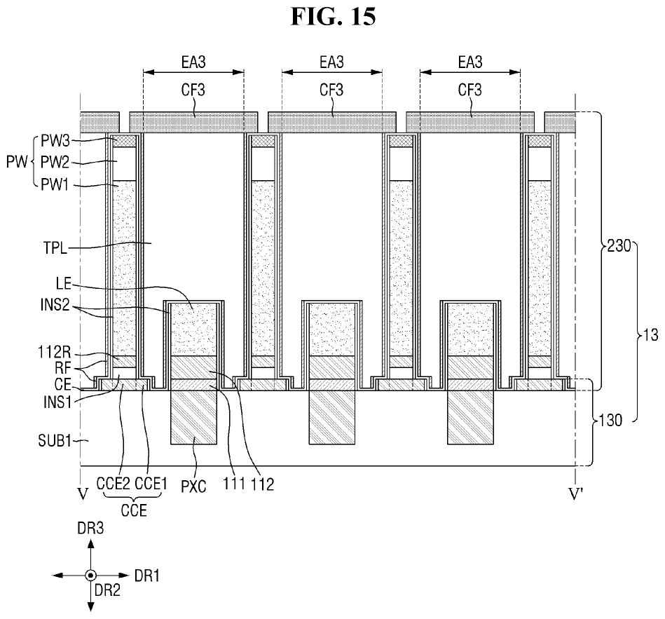

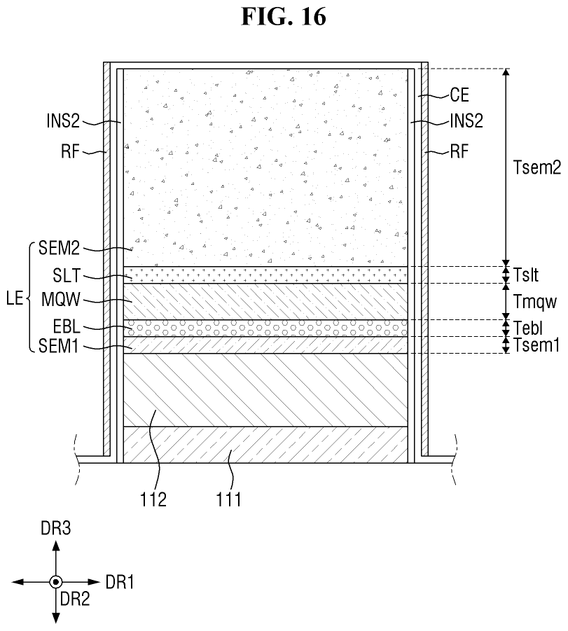

FIG. 13 is a cross-sectional view illustrating a display panel taken along line III-III′ of FIG. 7. FIG. 14 is a cross-sectional view illustrating a display panel taken along line IV-IV′ of FIG. 7. FIG. 15 is a cross-sectional view illustrating a display panel taken along line V-V′ of FIG. 7. FIG. 16 is an enlarged cross-sectional view of a light-emitting element according to one or more embodiments.

Referring to FIGS. 7 and 13, the first display area DA1 of the first display panel 11 may include the plurality of pixels PX. The pixel PX may be defined as a minimum light-emitting unit capable of displaying any one of red, green, and blue light.

Each of the plurality of pixels PX included in the first display panel 11 may include the first emitting area EA1 for emitting light.

The first light-emitting area EA may include the light-emitting element LE emitting light. Although the light-emitting element LE has a circular planar shape, the present disclosure is not limited thereto. For example, the light-emitting element LE may have the polygonal shape including a quadrangular shape or an elliptical shape.

Each of the first light-emitting areas EA1 indicates an area for emitting the first light. Each of the first light-emitting areas EA1 may convert a portion of the third light emitted from the light-emitting element LE into first light and output the first light. As described above, the first light may be light in the red wavelength band.

Each first light-emitting area EA1 may be partitioned by a partition wall PW. The partition wall PW may be located to surround the light-emitting element LE. The partition wall PW may be spaced apart from the light-emitting element LE. The partition wall PW may have the planar shape of a mesh shape, a net shape, or a lattice shape.

The first light-emitting area EA1 defined by the partition wall PW may have the circular planar shape, but the present disclosure is not limited thereto. For example, the first light-emitting area EA1 defined by the partition wall PW may have the planar shape of the polygon including a quadrangle or an ellipse.

Each of the second light-emitting areas EA2 included in the second display panel 12 indicates an area for emitting second light. Each of the second light-emitting areas EA2 may convert a portion of the third light emitted from the light-emitting element LE into the second light and output the second light. As described above, the second light may be light in the green wavelength band.

Each of the third light-emitting areas EA3 included in the third display panel 13 indicates an area for emitting third light. Each of the third light-emitting areas EA3 may output the third light output from the light-emitting element LE as it is. As described above, the third light may be light in the blue wavelength band.

Referring to FIGS. 7 to 9 and 13 to 16, the first display panel 11 may include a semiconductor circuit layer 110 and a light-emitting element layer 210, and the second display panel 12 may include a semiconductor circuit layer 120 and a light-emitting element layer 220, and the third display panel 13 may include a semiconductor circuit layer 130 and a light-emitting element layer 230.

Each of the semiconductor circuit layers 110, 120, and 130 may include the first substrate SUB1, a plurality of pixel circuit parts PXC, and pixel electrodes 111.

The first substrate SUB1 may be a silicon wafer substrate. The first substrate SUB1 may include single crystal silicon.

Each of the plurality of pixel circuit units PXC may be located on the first substrate SUB1. Each of the plurality of pixel circuit units PXC may include a complementary metal-oxide semiconductor (CMOS) circuit formed using the semiconductor process. Each of the plurality of pixel circuit units PXC may include at least one transistor formed through the semiconductor process. Also, each of the plurality of pixel circuit units PXC may further include at least one capacitor formed through the semiconductor process.

The plurality of pixel circuit units PXC may be located in the display area DA. Each of the plurality of pixel circuit units PXC may be connected to a corresponding pixel electrode 111. That is, the plurality of pixel circuit units PXC and the plurality of pixel electrodes 111 may be connected in a one-to-one correspondence. Each of the plurality of pixel circuit units PXC may apply a pixel voltage or an anode voltage to the pixel electrode 111.

Each of the pixel electrodes 111 may be located on a corresponding pixel circuit unit PXC. Each of the pixel electrodes 111 may be an exposed electrode exposed from the pixel circuit unit PXC. That is, each of the pixel electrodes 111 may protrude from the upper surface of the pixel circuit unit PXC. Each of the pixel electrodes 111 may be integrally formed with the pixel circuit unit PXC. Each of the pixel electrodes 111 may receive the pixel voltage or the anode voltage from the pixel circuit unit PXC. The pixel electrodes 111 may include aluminum (Al).

Each of the light-emitting element layers 210, 220, and 230 may be a layer for emitting light including the first light-emitting area EA1, the second light-emitting area EA2, and the third light-emitting area EA3. The light-emitting element layers 210, 220, and 230 may include connection electrodes 112, a common connection electrode CCE, light-emitting elements LE, a first insulating film INS1, a conductive pattern 112R, the partition wall PW, a second insulating film INS2, the common electrode CE, a reflective film RF, and a plurality of color filters CF1, CF2, and CF3. Here, the light-emitting element layer 210 of the first display panel 11 and the light-emitting element layer 220 of the second display panel 12 may include a wavelength conversion layer QDL, while the light-emitting element layer 230 of the third display panel 13 may include a transparent layer TPL instead of the wavelength conversion layer QDL.

Each of the connection electrodes 112 may be located on the corresponding pixel electrode 111. That is, the connection electrodes 112 may be connected to the pixel electrodes 111 in a one-to-one correspondence. The connection electrodes 112 may serve as a bonding metal for bonding the pixel electrodes 111 and the light-emitting elements LE in a manufacturing process. For example, the connection electrodes 112 may include at least one of gold (Au), copper (Cu), aluminum (Al), and/or tin (Sn). Alternatively, the connection electrodes 112 may include a first layer including any one of gold (Au), copper (Cu), aluminum (Al), and tin (Sn) and a second layer including another one of gold (Au), copper (Cu), aluminum (Al), and tin (Sn. In this case, the second layer may be located on the first layer.

The common connection electrode CCE may be located apart from the pixel electrode 111 and the connection electrode 112. The common connection electrode CCE may be located to surround the pixel electrode 111 and the connection electrode 112.

The common connection electrode CCE may include a first common connection electrode CCE1 located in the first to third light-emitting areas EA1, EA2, and EA3 and a second common connection electrode CCE2 overlapping the partition wall PW in the third direction DR3.

The common connection electrode CCE may receive the common voltage connected to one of the first pads of the first pad units of the first to third non-display areas NDA1, NDA2, and NDA3 (e.g., the first pad PD11 of the first pad unit PDA11 of the first non-display area NDA1). The common connection electrode CCE may include the same material as the connection electrodes 112. For example, the common connection electrode CCE may include at least one of gold (Au), copper (Cu), aluminum (Al), and/or tin (Sn). When each of the connection electrodes 112 includes the first layer and the second layer, the common connection electrode CCE may include the same material as the first layer of each of the connection electrodes 112.

Each of the light-emitting element layers 210, 220, and 230 may include first to third light-emitting areas EA1, EA2, and EA3 partitioned by the partition wall PW, respectively. Any one of the light-emitting element LE, the wavelength conversion layer QDL, and a plurality of color filters CF1 and CF2 may be located in each of the first and second light-emitting areas EA1 and EA2. The light-emitting element LE, the transparent layer TPL, and a third color filter CF3 may be located in each of the third light-emitting areas EA3.

Each of the light-emitting elements LE may be located on the connection electrode 112. The light-emitting element LE may be a vertical light-emitting diode element extending in the third direction DR3. That is, the length of the light-emitting element LE in the third direction DR3 may be longer than that in the horizontal direction. The length in the horizontal direction refers to the length of the first direction DR1 or the length of the second direction DR2. For example, the length of the light-emitting element LE in the third direction DR3 may be about 1 μm to about 5 μm.

The light-emitting element LE may be a micro light-emitting diode element or a nano light-emitting diode element.

As shown in FIG. 16, the light-emitting element LE may include a first semiconductor layer SEM1, an electron-blocking layer EBL, an active layer MQW, a superlattice layer SLT, and a second semiconductor layer SEM2 in the third direction DR3. The first semiconductor layer SEM1, the electron-blocking layer EBL, the active layer MQW, the superlattice layer SLT, and the second semiconductor layer SEM2 may be sequentially stacked in the third direction DR3.

The first semiconductor layer SEM1 may be located on the connection electrode 112. The first semiconductor layer SEM1 may be doped with a first conductivity type dopant, such as Mg, Zn, Ca, Se, or Ba. For example, the first semiconductor layer SEM1 may be p-GaN doped with P-type Mg. A thickness Tsem1 of the first semiconductor layer SEM1 may be about 30 nm to about 200 nm.

The electron-blocking layer EBL may be located on the first semiconductor layer SEM1. The electron-blocking layer EBL may be a layer for suppressing, reducing, or preventing too many electrons from flowing into the active layer MQW. For example, the electron-blocking layer EBL may be p-AlGaN doped with P-type Mg. A thickness Teb1 of the electron-blocking layer (EBL) may be about 10 nm to about 50 nm. The electron-blocking layer EBL may be omitted.

The active layer MQW may be located on the electron-blocking layer EBL. The active layer MQW may emit light by combining electron-hole pairs according to electrical signals applied through the first semiconductor layer SEM1 and the second semiconductor layer SEM2. The active layer MQW may emit third light having a central wavelength range of about 450 nm to about 495 nm, that is, light in the blue wavelength band.

The active layer MQW may include a material having a single or multiple quantum well structure. When the active layer MQW includes a material having a multi-quantum well structure, a plurality of well layers and barrier layers may be alternately stacked. In this case, the well layer may be formed of InGaN, and the barrier layer may be formed of GaN or AlGaN but is not limited thereto. A thickness of the well layer may be about 1 nm to about 4 nm, and the thickness of the barrier layer may be about 3 nm to about 10 nm.

Alternatively, the active layer MQW may have a structure in which a semiconductor material having a large band gap energy and a semiconductor material having a small band gap energy are alternately stacked with each other and may include other group 3 to group 5 semiconductor materials depending on the wavelength band of the emitted light. The light emitted by the active layer is not limited to the third light (light in the blue wavelength band) and may emit second light (light in the green wavelength band) or first light (light in the red wavelength band) depending on circumstances.

The superlattice layer SLT may be located on the active layer MQW. The superlattice layer SLT may be a layer for relieving stress between the second semiconductor layer SEM2 and the active layer MQW. For example, the superlattice layer SLT may be formed of InGaN or GaN. A thickness Tslt of the superlattice layer SLT may be about 50 nm to about 200 nm. The superlattice layer SLT may be omitted.

The second semiconductor layer SEM2 may be located on the superlattice layer SLT. The second semiconductor layer SEM2 may be doped with a second conductivity type dopant, such as Si, Ge, or Sn. For example, the second semiconductor layer SEM2 may be n-GaN doped with N-type Si. A thickness Tsem2 of the second semiconductor layer SEM2 may be about 500 nm to about 1 μm.

A first insulating layer INS1 may be located on the common connection electrode CCE. The first insulating layer INS1 may be formed of an inorganic layer, such as a silicon oxide layer (SiO₂), an aluminum oxide layer (Al₂O₃), or a hafnium oxide layer (HfOₓ).

The conductive pattern 112R may be located on the first insulating layer INS1. The conductive pattern 112R may be located between the first insulating layer INS1 and the partition wall PW in the third direction DR3.

The conductive pattern 112R is a residue formed through the same process as the connection electrodes 112 and the common connection electrode CCE. Therefore, the conductive pattern 112R may include the same material as the connection electrodes 112 and the common connection electrode CCE. For example, the conductive pattern 112R may include at least one of gold (Au), copper (Cu), aluminum (Al), and/or tin (Sn). When each of the connection electrodes 112 includes the first layer and the second layer, the conductive pattern 112R may include the same material as the second layer of each of the connection electrodes 112.

The partition wall PW may be located on the conductive pattern 112R. The partition wall PW may be located apart from each of the light-emitting elements LE. The partition wall PW is located to surround each of the light-emitting elements LE and may partition the light-emitting areas EA1, EA2, and EA3.

The partition wall PW may include a first partition wall PW1, a second partition wall PW2, and a third partition wall PW3 as shown in FIGS. 12 to 14 but is not limited thereto. At least a portion of the first partition wall PW1 may include the same material as that of the light-emitting element LE. The second partition wall PW2 is located on the first partition wall PW1 and may be formed of the inorganic layer, such as a silicon oxide layer (SiO₂), an aluminum oxide layer (Al₂O₃), or a hafnium oxide layer (HfOₓ). The third partition wall PW3 may be located on the second partition wall PW2. The third partition wall PW3 may include a conductive material, such as nickel (Ni).

The second insulating layer INS2 may be located on side surfaces of the common connection electrode CCE, side surfaces of the partition wall PW, respective side surfaces of the pixel electrodes 111, side surfaces of each of the connection electrodes 112, and side surfaces of each of the light-emitting elements LE. The second insulating layer INS2 may be formed of the inorganic layer, such as a silicon oxide layer (SiO₂), an aluminum oxide layer (Al₂O₃), or a hafnium oxide layer (HfOₓ). The thickness of the second insulating layer INS2 may be about 0.1 μm.

The common electrode CE may be located on top and side surfaces of each of the light-emitting elements LE and on top and side surfaces of the partition wall PW. That is, the common electrode CE may be located to cover the top and side surfaces of each of the light-emitting elements LE and the top and side surfaces of the partition wall PW.

The common electrode CE may contact the second insulating layer INS2 located on side surfaces of the first common connection electrode CCE1, side surfaces of the partition wall PW, each side surfaces of the pixel electrodes 111, each side surfaces of the connection electrodes 112, and each side surface of the light-emitting elements LE. Also, the common electrode CE may contact the upper surface of the first common connection electrode CCE1, the upper surface of each of the light-emitting elements LE, and the upper surface of the partition wall PW.

The common electrode CE may contact the exposed upper surface of the first common connection electrode CCE1, which is not covered by the second insulating layer INS2 and the upper surface of the light-emitting element LE at the edge of each of the first to third light-emitting areas EA1, EA2, and EA3. Accordingly, the common voltage supplied to the common connection electrode CCE may be supplied to the light-emitting element LE. One end of the light-emitting element LE may receive the pixel voltage or anode voltage of the pixel electrode 111 through the connection electrode 112 and the other end may receive the common voltage through the common electrode CE. The light-emitting element LE may emit light with a luminance (e.g., predetermined luminance) according to a voltage difference between the pixel voltage and the common voltage.

The common electrode CE may include a transparent conductive material. The common electrode CE may be formed of a transparent conductive oxide (TCO), such as indium tin oxide (ITO) or indium zinc oxide (IZO). The common electrode CE may have a thickness of about 0.1 μm.

The reflective film RF serves to reflect light that travels in up, down, left, and right side directions, not in an upper direction, among light emitted from the light-emitting element LE. The reflective film RF may include a metal material having high reflectivity, such as aluminum (Al). The thickness of the reflective film RF may be about 0.1 μm. The reflective film RF may contact the common electrode CE.

Referring to FIGS. 12 and 13, the wavelength conversion layer QDL may be located on the light-emitting element LE in the first light-emitting area EA1 and the second light-emitting area EA2. The wavelength conversion layer QDL may be located to cover the light-emitting element LE in the first light-emitting area EA1 and the second light-emitting area EA2.

The wavelength conversion layer QDL may include a base resin BRS and wavelength conversion particles WCP. The base resin BRS may include a light-transmitting organic material. For example, the base resin BRS may include an epoxy-based resin, an acrylic-based resin, a cardo-based resin, or an imide-based resin.

The wavelength conversion particle WCP may convert first light incident from the light-emitting element LE into third light, or may convert second light incident from the light-emitting element LE into third light. For example, the wavelength conversion particle WCP may convert light in the red wavelength band into light in the blue wavelength band. As another example, the wavelength conversion particle WCP may convert light in the green wavelength band into light in the blue wavelength band. The wavelength conversion particle WCP may be a quantum dot (QD), a quantum rod, a fluorescent material or a phosphorescent material. The quantum dot may include a group IV nanocrystal, a group II-VI compound nanocrystal, a group III-V compound nanocrystal, a group IV-VI nanocrystal, or a combination thereof.

The quantum dots may include a core and a shell overcoating the core. The core is not limited thereto, but it may be at least one of, for example, CdS, CdSe, CdTe, ZnS, ZnSe, ZnTe, GaN, GaP, GaAs, GaSb, AlN, AIP, AIAs, AlSb, InP, InAs, InSb, SiC, Ca, Se, In, P, Fe, Pt, Ni, Co, Al, Ag, Au, Cu, FePt, Fe₂O₃, Fe₃O₄, Si, and/or Ge. The shell is not limited to this, but it may include at least one of, for example, ZnS, ZnSe, ZnTe, CdS, CdSe, CdTe, HgS, HgSe, HgTe, AlN, AIP, AIAs, AlSb, GaN, GaP, GaAs, GaSb, GaSe, InN, InP, InAs, InSb, TIN, TIP, TIAs, TISb, PbS, PbSe, and/or PbTe.

The wavelength conversion layer QDL may further include a scattering body for scattering the light of the light-emitting element LE in a random direction. In this case, the scattering body may include metal oxide particles or organic particles. For example, the metal oxide may be titanium oxide (TiO₂), zirconium oxide (ZrO₂), aluminum oxide (Al₂O₃), indium oxide (In₂O₃), zinc oxide (ZnO), or tin oxide (SnO₂). Also, the organic particles may include an acrylic resin or a urethane resin. The scatterers may have a diameter of several to several tens of nanometers.

First and second color filters CF1 and CF2 may be located on the wavelength conversion layer QDL in the first and second emission areas EA1 and EA2, respectively. Also, the first and second color filters CF1 and CF2 may be located on the partition wall PW. The first and second color filters CF1 and CF2 transmit any one of the first and second light and absorb, reduce, or block the third light.

Referring to FIG. 15, the transparent layer TPL may be located on the light-emitting element LE in the third light-emitting area EA3. The transparent layer TPL may be located to cover the light-emitting element LE in the third light-emitting area EA3.

The transparent layer TPL may include the light-transmitting organic material. For example, the base resin BRS may include the epoxy-based resin, the acrylic-based resin, the cardo-based resin, or the imide-based resin. The transparent layer TPL may transmit the third light incident from the light-emitting element LE without absorbing it. For example, the transparent layer TPL may transmit light in the blue wavelength band without absorbing it.

The third color filter CF3 may be located on the transparent layer TPL in the third light-emitting area EA3. Also, the third color filter CF3 may be located on the partition wall PW. The third color filter CF3 transmits third light and absorbs, reduces, or blocks first and second light.

In one or more embodiments, a black matrix may be located between the first to third color filters CF1, CF2, and CF3. The black matrix may include an inorganic black pigment, such as carbon black or an organic black pigment.

In the display device 1 according to one or more embodiments, the first to third display panels 11, 12, and 13 emitting monochromatic light are located on one circuit board MB having different thicknesses. As a result, it may be implemented compactly, and cost may be reduced.

In addition, light may be vertically incident on three side surfaces of the light coupler 20 by locating the circuit board MB having the first to third bendable connectors BD1, BD2, and BD3 on the bottom surfaces of the first to third display panels 11, 12, and 13 emitting monochromatic light. Therefore, the display device 1 may display a multi-color image using a monochromatic display panel.

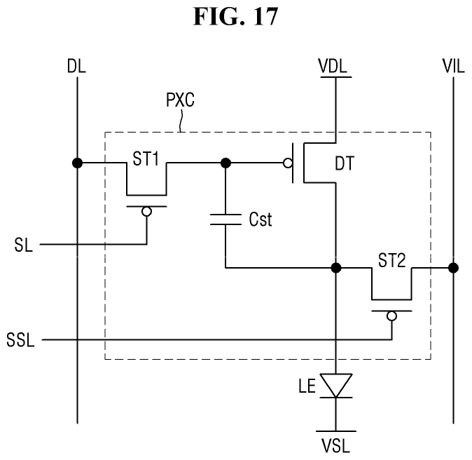

FIG. 17 is a pixel circuit diagram of a display device according to one or more embodiments.

Referring to FIG. 17, each of the plurality of pixels PX may include the light-emitting element LE and the pixel circuit unit PXC that controls the amount of light emitted from the light-emitting element LE. The amount of light emitted from the light-emitting element LE may be proportional to the driving current Ids. The light-emitting element LE may be an inorganic light-emitting element including an anode electrode, a cathode electrode, and the inorganic semiconductor located between the anode electrode and the cathode electrode. For example, the light-emitting element LE may be the micro light-emitting diode.

The anode electrode of the light-emitting element LE may be connected to a source electrode of the driving transistor DT, and the cathode electrode may be connected to a second power supply line VSL supplied with a low potential voltage that is lower than a high potential voltage. The circuit diagram of FIG. 7 is exemplified that the anode electrode of the light-emitting element LE is a pixel electrode (“111” in FIG. 13) and the cathode electrode is a common electrode (“CE” in FIG. 13).

The driving transistor DT adjusts the current flowing from the first power supply line VDL to which the first power supply voltage is supplied to the light-emitting element LE according to the voltage difference between a gate electrode and the source electrode. The gate electrode of the driving transistor DT may be connected to the first electrode of the first transistor ST1, the source electrode may be connected to the anode electrode of the light-emitting element LE, and a drain electrode may be connected to the first power supply line VDL to which the high potential voltage is applied.

The first transistor ST1 is turned-on by a scan signal of the scan line SL to connect a data line DL to the gate electrode of the driving transistor DT. The gate electrode of the first transistor ST1 may be connected to the scan line SL, the first electrode may be connected to the gate electrode of the driving transistor DT, and the second electrode may be connected to the data line DL.

The second transistor ST2 is turned-on by a sensing signal of a sensing signal line SSL to connect an initialization voltage line VIL to the source electrode of the driving transistor DT. The gate electrode of the second transistor ST2 may be connected to the sensing signal line SSL, the first electrode may be connected to the initialization voltage line VIL, and the second electrode may be connected to the source electrode of the driving transistor DT.

The first electrode of each of the first and second transistors ST1 and ST2 may be the source electrode, and the second electrode may be the drain electrode, but is not limited thereto. That is, the first electrode of each of the first and second transistors ST1 and ST2 may be the drain electrode, and the second electrode may be the source electrode.

A capacitor Cst is formed between the gate electrode and the source electrode of the driving transistor DT. The capacitor Cst stores a difference voltage between the gate voltage and the source voltage of the driving transistor DT.

However, this is just an example, and the pixel circuit unit PXC may have a structure further including a plurality of transistors.

In addition, although FIG. 17 illustrates the case where the driving transistor DT and the first and second transistors ST1 and ST2 are NMOS transistors, some or all transistors may be provided as PMOS transistors.

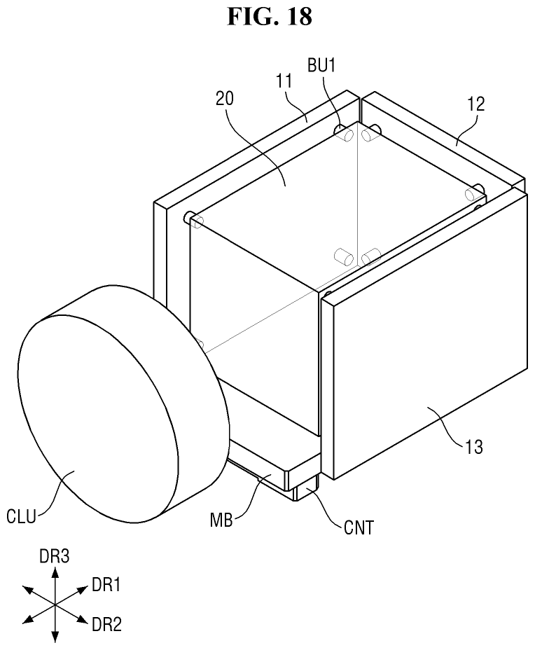

Hereinafter, a coupling method between the display panels 11, 12, and 13 and the light coupler 20 will be described with reference to FIGS. 18 to 20.

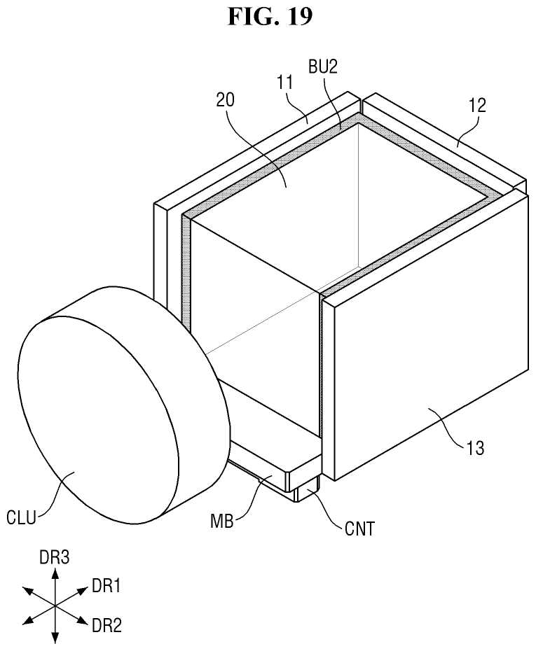

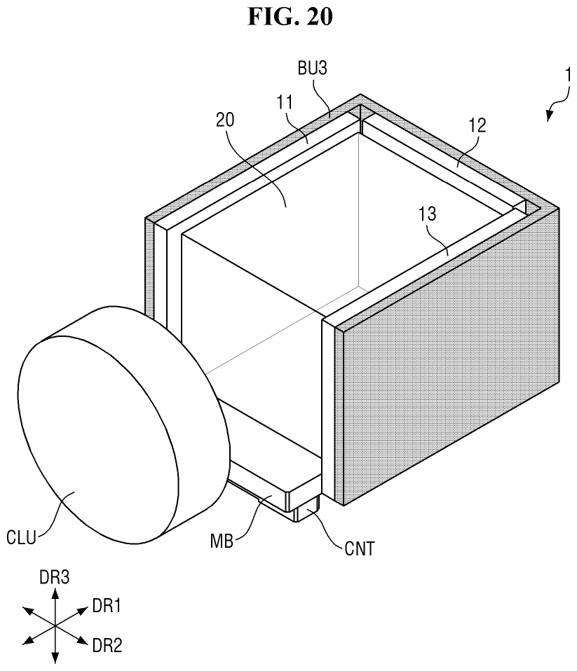

FIG. 18 is a perspective view of a display device using a first coupler (e.g., first coupling member) according to one or more embodiments. FIG. 19 is a perspective view of a display device using a second coupler (e.g., a second coupling member) according to one or more other embodiments. FIG. 20 is a perspective view of a display device using a housing according to one or more other embodiments.

Referring to FIG. 18, a first coupler BU1 may be located at least one place between the first display panel 11, the second display panel 12, and/or the third display panel 13 and the light coupler 20. The light coupler 20 may be coupled to the first display panel 11, the second display panel 12, and the third display panel 13 through the first coupler BU1. The first coupler BU1 is located in the non-display area of the first display panel 11 and is coupled to the light coupler 20.

The first coupler BU1 may be an adhesive that is cured after the panel and the light coupler 20 are arranged. For example, the first coupler BU1 may be an optical adhesive, such as optically clear adhesive (OCA) or optically clear resin (OCR), but is not limited thereto.

Referring to FIG. 19, a second coupler BU2 may be located between each of the first display panel 11, the second display panel 12, and the third display panel 13 and the light coupler 20. The light coupler 20 may be coupled to the first display panel 11, the second display panel 12, and the third display panel 13 through the second coupler BU2.

In one or more other embodiments, the second coupler BU2 may be located in the entire area overlapping the display area between each of the first display panel 11, the second display panel 12, and the third display panel 13 and the light coupler 20. In this case, the second coupler BU2 may include an adhesive material that has thermal stability and changes relatively little according to temperature.

The second coupler BU2 is located in the non-display area of the first display panel 11 and is coupled to the light coupler 20. For example, the second coupler BU2 is located between the first display panel 11 and the facing light coupler 20 to surround the display area of the first display panel 11 so that the light emitted from the first display panel 11 from escaping between the first display panel 11 and the light coupler 20.

The display device 1 of FIG. 20 may include a housing BU3. The housing BU3 is a member that mechanically couples the first display panel 11, the second display panel 12, and the third display panel 13 to the light coupler 20. The housing BU3 may include an insulating polymer material, such as polyimide.

The display device 1 might not use individual circuit boards MB for each display panel 11, 12, and 13, and the display panels 11, 12, and 13 may share the connector CNT and various passive elements included on one circuit board MB. That is, a driving signal may be applied to each of the first to third display panels 11, 12, and 13 using one circuit board MB, and the power may be supplied. Therefore, the display device 1 may display a multi-color image using a monochromatic display panel.

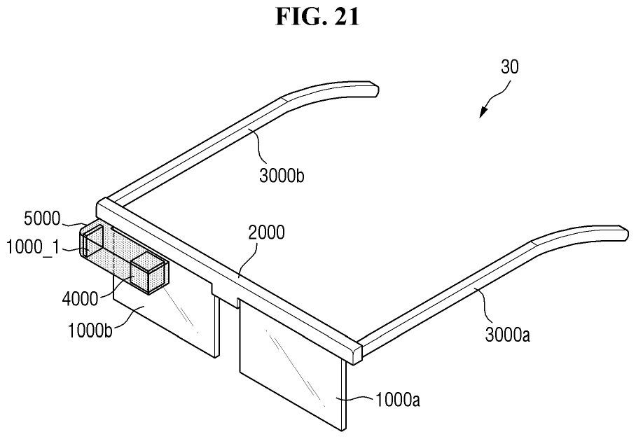

FIG. 21 is a diagram illustrating a virtual reality device including a display device according to one or more embodiments. FIG. 21 illustrates a virtual reality device 30 in which the display device 1000_1 according to one or more embodiments is used.

Referring to FIG. 21, the virtual reality device 30 according to one or more embodiments may be a device in a form of glasses. The virtual reality device 30 according to one or more embodiments may include a display device 1000_1, a left-eye lens 1000a, a right-eye lens 1000b, a support frame 2000, left and right legs 3000a and 3000b, a mirror (e.g., a reflective member) 4000, and a display device housing 5000.

FIG. 21 illustrates the virtual reality device 30 including the two legs 3000a and 3000b. However, the disclosure is not limited thereto. The virtual reality device 30 according to one or more embodiments may be used in a head-mounted display including a head-mounted band that may be mounted on a head instead of the legs 3000a and 3000b. For example, the virtual reality device 30 according to one or more embodiments may not be limited to the example shown in FIG. 21, and may be applied in various forms and in various electronic devices.

The display device housing 5000 may receive the display device 1000_1 and the mirror 4000. An image displayed on the display device 1000_1 may be reflected from the mirror 4000 and provided to a user's right eye through the right-eye lens 1000b. Thus, the user may view a virtual reality image displayed on the display device 100_10 via the right eye.

FIG. 21 illustrates that the display device housing 5000 is located at a right end of the support frame 2000. However, one or more embodiments of the disclosure is not limited thereto. For example, the display device housing 5000 may be located at a left end of the support frame 2000. In this case, the image displayed on the display device 1000_1 may be reflected from the mirror 4000 and provided to the user's left eye via the left-eye lens 10a. Thus, the user may view the virtual reality image displayed on the display device 1000_1 via the left eye. As another example, the display device housing 5000 may be located at each of the left end and the right end of the support frame 2000. In this case, the user may view the virtual reality image displayed on the display device 1000_1 via both the left eye and the right eye.

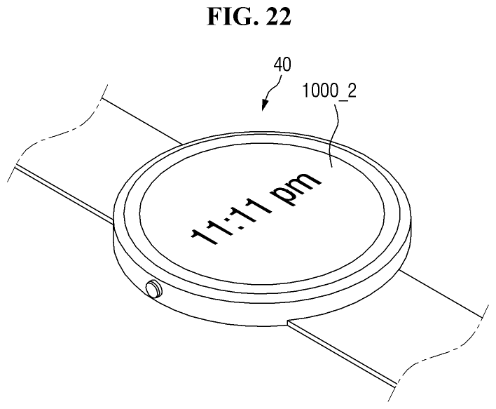

FIG. 22 is a diagram illustrating a smart device including a display device according to one or more embodiments.

Referring to FIG. 22, a display device 1000_2 according to one or more embodiments may be applied to a smart watch 40 as one of smart devices.

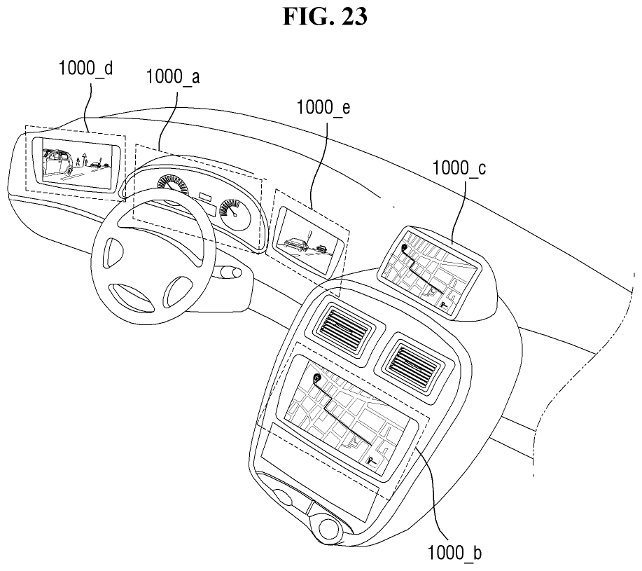

FIG. 23 is a diagram illustrating a vehicle including a display device according to one or more embodiments. FIG. 23 illustrates a vehicle in which display devices according to one or more embodiments are used.

Referring to FIG. 23, the display devices 1000_a, 1000_b, and 1000_c according to one or more embodiments may be applied to the dashboard of the vehicle, applied to the center fascia of the vehicle, or applied to a CID (Center Information Display) located on the dashboard of the vehicle. Further, each of the display devices 1000_d and 1000_e according to one or more embodiments may be applied to each room mirror display that replaces each of side-view mirrors of the vehicle.

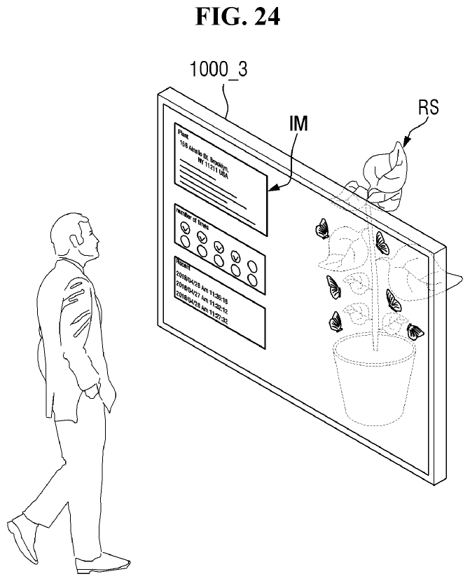

FIG. 24 is a diagram illustrating a transparent display device including a display device according to one or more embodiments.

Referring to FIG. 24, a display device according to one or more embodiments may be applied to a transparent display device. The transparent display device may transmit light therethrough while displaying an image IM thereon. Therefore, a user located in front of the transparent display device may not only view the image IM displayed on the display device 1000_3, but also may view an object RS or a background located in rear of the transparent display device. In case that the display device 1000_3 is applied to the transparent display device, the first substrate SUB1 of the display device 1000_3 shown in FIG. 7 may include a light transmitting portion that may transmit light therethrough, or may be made of a material that may transmit light therethrough.

Each feature of the various embodiments of the present disclosure may be partially or entirely combined or combined with each other, technically various interlocking and driving are possible, and each embodiment may be implemented independently of each other or may be implemented together in an association relationship.

In concluding the detailed description, those skilled in the art will appreciate that many variations and modifications can be made to the embodiments without substantially departing from the aspects of the disclosure. Therefore, the disclosed embodiments of the disclosure are used in a generic and descriptive sense only and not for purposes of limitation.

What is claimed is:

1. A display device comprising:
a first display panel for emitting a first light;
a second display panel for emitting second light;
a third display panel for emitting third light; and
a light coupler for combining the first light, the second light, and the third light, and for outputting combined light; and
a circuit board on a first surface of the light coupler, and electrically connected to the first display panel, to the second display panel, and to the third display panel,
wherein the first display panel, the second display panel, and the third display panel are respectively on a second surface, a third surface, and a fourth surface of the light coupler.

2. The display device of claim 1, wherein the circuit board comprises a connector or a connector connection unit connected to an external device,
wherein the connector or the connector connection unit is electrically connected to the first display panel, to the second display panel, and to the third display panel.

3. The display device of claim 2, wherein the circuit board comprises:
a first circuit pad unit electrically connected to the first display panel;
a second circuit pad unit electrically connected to the second display panel;
a third circuit pad unit electrically connected to the third display panel;
a first conductive line connected from the connector or the connector connection unit to the first circuit pad unit;
a second conductive line connected from the connector or the connector connection unit to the second circuit pad unit; and
a third conductive line connected from the connector or the connector connection unit to the third circuit pad unit.

4. The display device of claim 3, further comprising a bent first flexible circuit board between the first display panel and the circuit board;
a bent second flexible circuit board between the second display panel and the circuit board; and
a bent third flexible circuit board between the third display panel and the circuit board.

5. The display device of claim 4, wherein the first flexible circuit board electrically connects the first circuit pad unit and the first display panel,
wherein the second flexible circuit board electrically connects the second circuit pad unit and the second display panel, and
wherein the third flexible circuit board electrically connects the third circuit pad unit and the third display panel.

6. The display device of claim 1, wherein the first surface is perpendicular to the second surface, to the third surface, and to the fourth surface, and
wherein the second surface and the third surface face each other.

7. The display device of claim 1, wherein the light coupler reflects the first light, and comprises a first reflective transmissive film that transmits the second light and the third light, and a second reflective transmissive film that reflects the third light and transmits the first light and the second light.

8. The display device of claim 1, further comprising one or more lenses in an output direction of the combined light from the light coupler to converge or focus the combined light in one direction.

9. The display device of claim 1, wherein the circuit board further comprises passive elements for applying separate signals to the first display panel, to the second display panel, and to the third display panel.

10. The display device of claim 1, wherein the first display panel, the second display panel, the third display panel, and the light coupler are fixed by an adhesive.

11. The display device of claim 10, wherein the adhesive is one of cement or optical adhesive.

12. The display device of claim 10, wherein the adhesive comprises at least one of a black-based dye or a metal.

13. The display device of claim 1, further comprising a housing surrounding the display panel, and coupling the display panel and the light coupler.

14. A display device comprising:
a first display panel for emitting a first light;
a second display panel for emitting second light;
a third display panel for emitting third light; and
a circuit board comprising first conductive lines connected to the first display panel, second conductive lines connected to the second display panel, third conductive lines connected to the third display panel, and a connector connected to an external device and connected to the first conductive lines, the second conductive lines, and the third conductive lines.

15. The display device of claim 14, wherein the circuit board further comprises passive elements for applying separate signals to the first display panel, to the second display panel, and to the third display panel.

16. The display device of claim 14, wherein the circuit board comprises:
a first circuit pad unit electrically connected to the first display panel;
a second circuit pad unit electrically connected to the second display panel;
a third circuit pad unit electrically connected to the third display panel,
one of the first conductive lines connected from the connector or a connector connection unit to the first circuit pad unit;
one of the a second conductive lines connected from the connector or the connector connection unit to the second circuit pad unit; and
one of the a third conductive lines connected from the connector or the connector connection unit to the third circuit pad unit.

17. The display device of claim 16, further comprising a first flexible circuit board between the first display panel and the circuit board;
a second flexible circuit board between the second display panel and the circuit board; and
a third flexible circuit board between the third display panel and the circuit board,
wherein the first flexible circuit board, the second flexible circuit board, and the third flexible circuit board are bent.

18. A display device comprising:
a first display panel for emitting a first light;
a second display panel for emitting second light;
a third display panel for emitting third light;
a circuit board comprising a connector connected to an external device, and a passive element for applying separate signals to the first display panel, to the second display panel, and to the third display panel; and
flexible circuit boards connecting each of the first display panel, the second display panel, and the third display panel to the circuit board,
wherein the connector is electrically connected to the first display panel, to the second display panel, and to the third display panel.

19. The display device of claim 18, further comprising:
a light coupler for combining the first light, the second light, and the third light, and for outputting combined light; and
one or more lenses in an output direction of the combined light from the light coupler to converge or focus the combined light in one direction.

20. The display device of claim 19, wherein the light coupler is configured to reflect the first light, and comprises a first reflective transmissive film for transmitting the second light and the third light, and a second reflective transmissive film for reflecting the third light and for transmitting the first light and the second light.
